(19) United States
(12) Patent Application Publication
(10) Pub. No.: US 2008/0083993 A1
(43) Pub. Date: Apr. 10, 2008

(54) Gold-Tin Solder Joints Having Reduced Embrittlement

(75) Inventors: Kejun Zeng, Coppell, TX (US); Donald Abbott, Norton, MA (US); Wei Qun Peng, Coppell, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/765,286

(22) Filed: Jun. 19, 2007

Related U.S. Application Data
(60) Provisional application No. 60/828,155, filed on Oct. 4, 2006.

(51) Int. Cl. H01L 23/52; H01L 21/00

(52) U.S. Cl. 257/777; 438/125; 257/E23.141; 257/E21.001

(57) ABSTRACT

A metal interconnection for two workplaces such as a semiconductor chip and an insulating substrate. The first workpiece (101) has a first contact pad (201) with a gold stud (110); the second workplace (103) is covered with an insulating layer (213) and a window in the layer to a second contact pad (211). The interconnection between the second pad and the gold stud is a 278° C. eutectic structure (111) with about 80 weight percent gold and about 20 weight percent tin. The eutectic structure has a Young's modulus of 59.2 GPa and a lamellar micro-structure of the phases Au₅Sn and AuSn. There is substantially no metallic tin at the second contact pad.

### FIELD OF THE INVENTION

The present invention is related in general to the field of metallurgical systems with application to electronic systems and semiconductor devices, and more specifically to solder joints with gold-tin eutectic structures and reduced brittleness.

### DESCRIPTION OF THE RELATED ART

The growing popularity of flip-chip assembly in the fabrication process flow of silicon integrated circuit (IC) devices is driven by several facts. First, the electrical performance of the semiconductor devices can be improved when the parasitic inductances correlated with conventional wire bonding interconnection techniques are reduced. Second, flip-chip assembly provides higher interconnection densities between chip and package than wire bonding. Third, flip-chip assembly consumes less silicon “real estate” than wire bonding, and thus helps to conserve silicon area and reduce device cost. And fourth, the fabrication cost can be reduced, when concurrent gang-bonding techniques are employed rather than consecutive individual bonding steps.

The conventional fabrication process uses tin/lead solder balls and their reflow technique as the standard method of ball bonding. In known technology, however, the achievable bump pitch is limited so that the number of connections on the available chip surface is severely restricted.

Efforts were undertaken to replace solder-based interconnecting balls with gold bumps, especially by an effort to create gold bumps by a modified wire ball technique. In this technique, the bumps are allowed to retain a small “tail” which is formed when the gold wire is broken off after the free air ball has been formed and pressured as a “bump” against the substrate. For gold stud bumps or gold-plated bumps, 25 μm diameter has been the lower value for devices in production for a while, but efforts are under way to reduce this diameter further. Typically, the gold bumps are created on the contact pads of semiconductor chips. Subsequently, the chips are attached to substrates using solder.

While conventional solders of lead/tin alloys have been used in electronic device fabrication for many years, environmental concerns have recently promoted an effort to eliminate the lead from the solder alloys and use pure tin, a tin alloy, or another solder without lead. Typically the tin-based alloy is deposited on the substrate contact pads.

When the gold bumps are joined to the substrate pads by reflowing the solder that has been deposited on the pads, a number of gold-tin intermetallics are formed. Because of the high dissolution rate of gold in the molten solders, the solder joints with gold bumps have, after one reflow, a large volume fraction of the intermetallic compound AuSn₄ that greatly embrittles the joints. After two or more reflows, the gold bumps may be completely consumed and intermtallic compounds such as AuSn₂ and AuSn are formed. The large volume fraction of gold/tin intermetallic compounds in the bulk solder, with AuSn₄ the major phase, causes severe gold embrittlement so that the assembly fails mechanical tests by cracking at the bump/chip interface.

For chips which have the gold bumps positioned on an aluminum layer, an additional problem appears after the consumption of the gold bump: In consecutive reflow operations (for many devices, three more reflows are needed), the aluminum/gold intermetallics may also be lost so that the aluminum pad loses its solderablity altogether.

### SUMMARY OF THE INVENTION

Applicants realize that a new approach needs to be taken for the chip-to-substrate assembly process. The assembly has to be performed so that the chip-to-substrate joints are reflowing only once so that the solder area will not be melted again in subsequent process steps. In addition, compliant gold has to be left over from the reflow process to absorb thermo-mechanical stress in device operation.

The assembly process of the invention is a coherent, low-cost method suitable for high and low lead counts, and for devices of any size including chip-scale devices. The assembled devices have excellent electrical performance, mechanical stability, and high product reliability. The fabrication method is easy to implement and flexible enough to be applied for different semiconductor product families including package-on-package. The innovation can be accomplished while shortening production cycle time and increasing throughput.

One embodiment of the invention is a metal interconnection for two workpieces, such as a semiconductor chip and an insulating substrate. The first workpiece has a first contact pad with a gold stud; the second workpiece is covered with an insulating layer and a window in the layer to a second contact pad. The interconnect ion between the second pad and the gold stud is a 278° C. eutectic structure with about 80 weight percent gold and about 20 weight percent tin. The eutectic structure has a Young's modulus of 53.2 GPa and a lamellar micro-structure of the phases Au₅Sn and AuSn. There is substantially no metallic tin at the second contact pad.

Another embodiment of the invention is a method for fabricating a metal interconnection. A first workpiece, such as a semiconductor chip, has a first contact pad with a metal surface bondable to gold. A free air gold ball is formed from a gold wire. The free air ball is then placed on the metal of the first contact pad and squeezed to create a deformed sphere. Finally, the wire is broken from the sphere to leave a gold stud of a first volume on the first pad.

Next, a second workplace, such as a substrate covered with an insulating layer of a height, is provided. A window in the layer exposes the metal of a second contact pad. Tin of a second volume is deposited on the metal of the second pad so that the second volume is less than about two thirds of the first volume.

The first and the second workpiece are aligned to bring the gold stud in contact with the tin layer. Thermal energy is applied to the first and the second workpiece to reach a reflow temperature of a few degrees above the eutectic temperature of 278° C. The temperature is maintained for a time sufficient to consume substantially all tin and a portion of the gold stud for forming the eutectic mixture of 80 weight percent gold and 20 weight percent tin. To reach the eutectic mixture, the dissolved portion of the first volume (gold) is 1.5 times the second volume (tin); the tin volume is two thirds of the gold volume.

It is a technical advantage of the invention that the leftover gold forms a stud shaped as a deformed sphere of a size sufficient to absorb thermomechanical stress.

It is another advantage of the invention that the resulting solder area of 80 weight percent gold and 20 weight percent tin will not be further melted in subsequent assembly processes because of its high melting temperature of 278° C. Any further dissolution of gold is thus greatly limited.

Another advantage is the fact that it is more difficult for potential microcracks to propagate in the eutectic structure of the invention than in conventional gold/tin solders with typical large, brittle AuSn₄ crystals. The interconnection reliability is thus greatly improved.

The joint reliability is further improved by having Au₅Sn at the gold/solder interface and (Au,Cu)₅Sn at the copper/solder interface.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates a schematic cross section of a first workplace such as a semiconductor chip interconnected by a metal structure to a second workpiece such an insulating substrate.

FIG. 2 depicts a schematic cross section of a close-up of one metallic interconnection with a eutectic structure according to the invention.

FIG. 3 shows the phase diagram of the gold/tin system to highlight the eutectic point at 278° C. used by the invention. First abscissa: Weight percent tin. Second abscissa: Atomic percent tin. Ordinate: Temperature (° C.).

FIG. 4 illustrates a perspective view of portions of the first workpiece and the second workpiece at certain steps of the fabrication process, according to the invention.

### DETAILED DESCRIPTION OF THE PREFERRED EMBODIMENTS

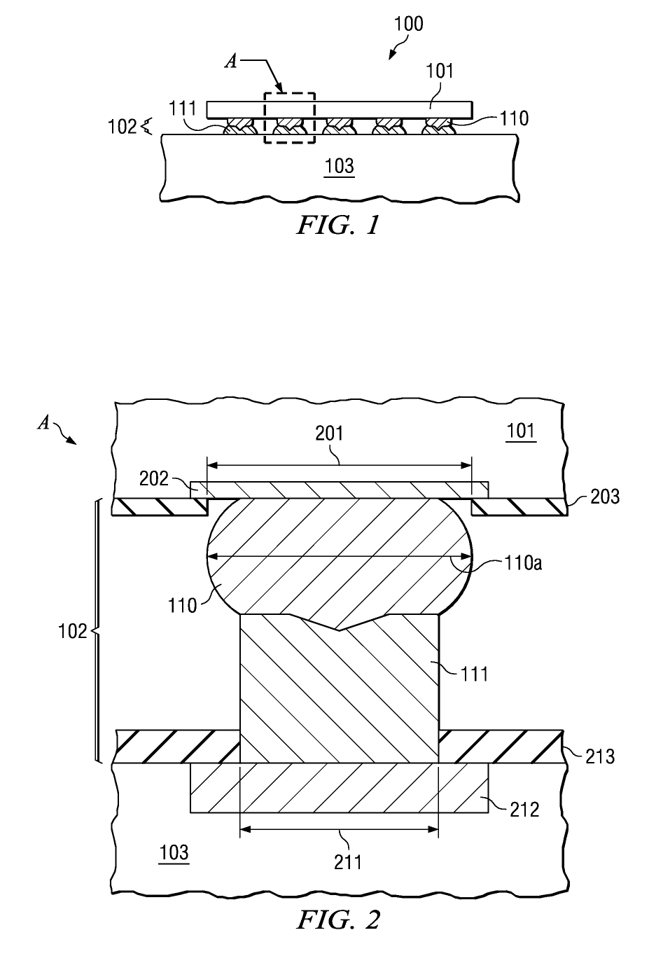

FIG. 1 illustrates schematically an apparatus generally designated 100, which includes a first workpiece 101 assembled by metal interconnections 102 on a second workpiece 103. As an example, the first workpiece 101 may be a semiconductor chip such as a silicon integrated circuit chip; the second workpiece may be an insulating substrate integral with patterned metal layers, such as an FR-4 board or a plastic film based on polyimide or epoxy compounds. The metal interconnections 102 are shown to be composed of two components, a metal stud 110 and solder 111. The metal studs 110 are preferably gold and are attached to the first workpiece 101; solder 111 is tin-based and is located on the second workpiece 103. Alternatively, metal studs 110 may be copper or a copper alloy. An individual apparatus “A” is enlarged in FIG. 2.

The apparatus “A” of FIG. 2 includes a portion of the first workpiece 101, a portion of the second workpiece 103, and one metal interconnection 102. First workpiece 101, for instance a semiconductor chip, has a first contact pad 201. As FIG. 2 shows, pad 201 includes gold (or copper) stud 110. Due to the fabrication method (see below), stud 110 may have the shape of a deformed sphere with diameter 110a. It is preferred especially for semiconductor chips that pad 201 further includes a metallic pad 202, which has a surface bondable to gold. As an example, metallic pad 202 may be a layer of aluminum. Alternatively, it may be a layer of copper with a thin surface layer of gold or palladium. Preferably, metallic pad 202 is exposed by a window in a protective overcoat 203, which defines the size of the pad. An overcoat example is one or more layers of silicon nitride or silicon oxynitride, which effectively protects the semiconductor chip against environmental disturbances and moisture.

The second workpiece 103, for instance an insulating substrate, has a protective layer 213 on its surface. A window of width 211 in layer 213 exposes the second contact pad 212 and defines the lateral dimension of the pad. As an example, contact pad 212 may be a layer of copper or copper alloy. The lateral dimension 211 may be the side of a rectangle for a rectangular window, or the diameter for a circular window. It is preferred that the second contact pad is circular with 211 as its diameter, because, as a deformed sphere, gold stud 110 also has an approximately circular contour. For controls in the fabrication method (see below) of the interconnection 102, it is preferred that diameter 211 is smaller than diameter 110a of the deformed gold sphere.

In addition to deformed gold sphere 110, metal interconnection 102 includes the 278° C. eutectic structure 111. The structure contacts the second pad 211 and the gold stud 110. The eutectic structure 111 has the outline of an approximate pillar or column with a diameter about equal to the lateral dimension of the window in layer 213. Eutectic structure 111 consists of about 80 weight percent gold and about 20 weight percent tin, formed in a eutectic mixture at 278° C. Eutectic structure 111 has a lamellar microstructure of the phases Au₅Sn and AuSn, but does practically not include brittle AuSn₄ crystals. Scallop-like Au₅Sn is also at the gold/solder interface, which is helpful to improve the joint reliability. At the copper/solder interface towards copper layer 212 is the compound (Au,Cu)₅Sn, also beneficial to high reliability.

Eutectic structure 111 has a Young's modulus of 59.2 GPa, as compared to 71.1 GPa of the brittle AuSn₄. The experience of applicants has shown that it is more difficult for potential microcracks to propagate in the eutectic structure 111 than in conventional gold/tin solders with typical large, brittle AuSn₄ crystals. The interconnection reliability is thus greatly improved.

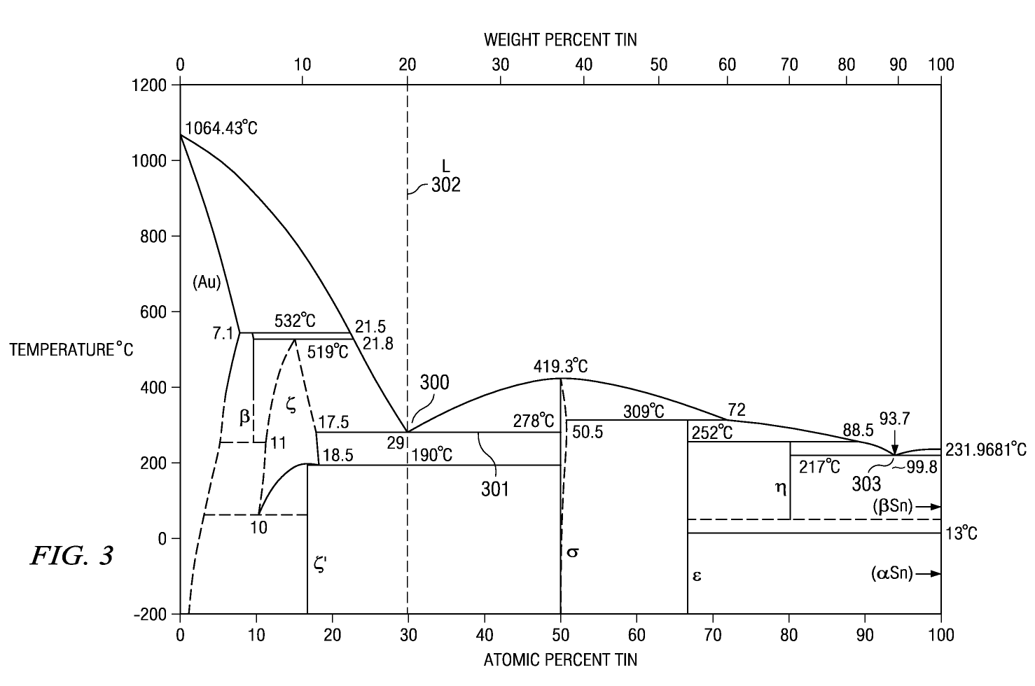

FIG. 3 shows the phase diagram of the gold/tin system to highlight the (first) eutectic point at 278° C. (designated 300) used by the invention. In FIG. 3, the first abscissa plots the weight percent tin and the second abscissa plots atomic percent tin. For tin, line 302 demarcates the 20 weight percent and 29 atomic percent points characteristic for the eutectic point employed by the invention. Clearly, the amount of tin needed for the eutectic mixture is small. The ordinate indicates the temperature in ° C. Line 301 demarcates the 278° C. temperature. The contributing phases for (first) eutectic point 300 are listed as Au₅Sn and AuSn; both phases have elastic characteristics and are thus beneficial for solder joint reliability.

In contrast, conventional gold/tin solders operate at the (second) eutectic point 303, which is characterized by 93.7 atomic percent tin, or 90 weight percent tin. Clearly, the amount of tin needed for the eutectic mixture is large. The eutectic point employed conventionally has a melting temperature of 217° C. The contributing phase for the (second) eutectic point is AuSn₄, which is brittle and harmful for the solder joint reliability.

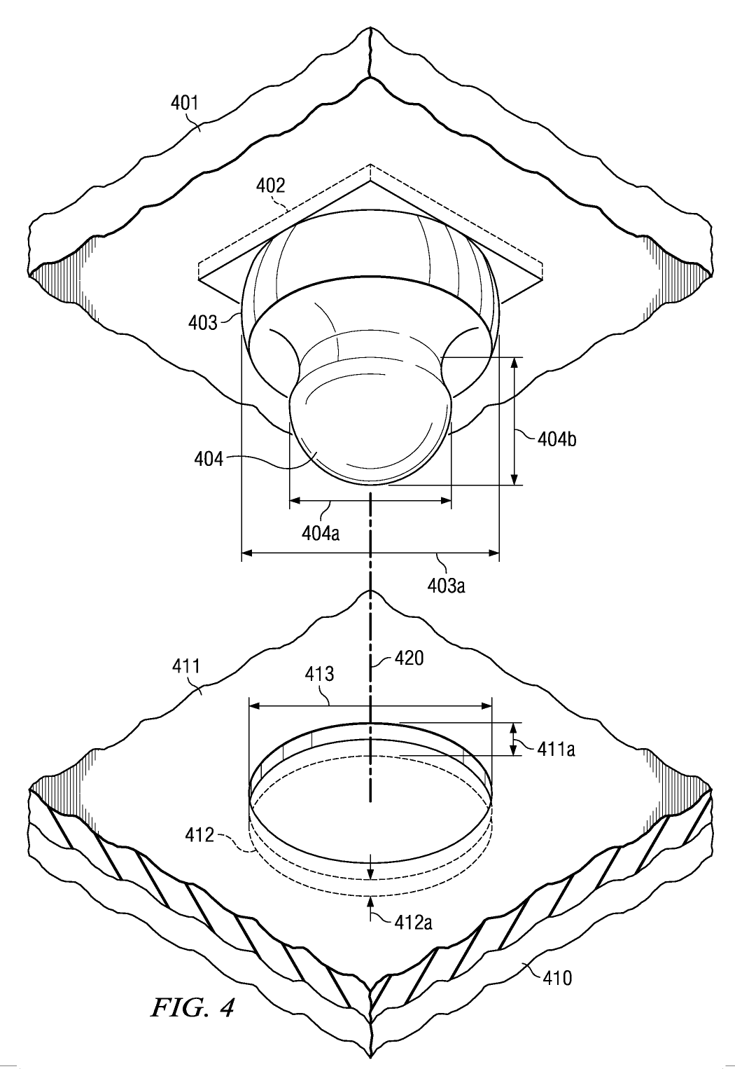

Another embodiment of the invention is a method for fabricating a metallic connection between two workpieces. FIG. 4 illustrates certain process steps of this method. A first workpiece 401 is supplied, for example a semiconductor chip, which has a first contact pad 402. The metal of pad 402 includes a surface bondable to gold; preferred metals are aluminum or aluminum-copper alloy.

In the next process step, a wire bonder with a capillary is selected suitable for round gold wires in the diameter range between 15 and 33 μm, preferably 20 to 25 μm. For subsequent bonding to aluminum pads and controlling the heat-affected zone in ball formation, the wire may include small contents of beryllium, copper, palladium, iron, silver, calcium or magnesium. From the length of the gold wire protruding from the capillary, a free air ball is formed using either a flame or a spark technique. The ball has a size with a preferred diameter from about 1.2 to 1.6 wire diameters, for example, between about 20 and 30 μm.

For bonding gold to aluminum, the semiconductor chip is positioned on a heated pedestal heated to a temperature between 150 and 300° C. The free air bail is placed on the pad 402 and pressed against the metallization of the pad. For pads of aluminum, a combination of compression force and ultrasonic energy creates the formation of gold-aluminum intermetallics and a strong metallurgical bond. The compression force is between about 17 and 75 g; the ultrasonic time between about 10 and 20 ms, the ultrasonic power between about 20 and 50 mW. At time of bonding, the temperature usually ranges from 150 to 270° C. As depicted in FIG. 4, the squeezed gold stud 403 looks like a deformed sphere with a diameter 403a.

The capillary is lifted and the wire is broken off from the squeezed sphere in the heat-affected mechanically weak zone. Dependent on the shape of the capillary orifice, stud 403 may have an additional truncated cone with a fiat top as shown in FIG. 4, or a small additional wire length attached. The complete gold stud on the first contact pad 402 has a first volume V_{stud}, which includes the squeezed ball 403 and any additional cone 404, or wire tail, or both.

Next, a second workpiece 410 is provided, for example an insulating substrate integral with at least one layer of patterned conductive lines. Preferably the metal of the layer is copper. Workpiece 410 is covered with an insulating layer 411; an example is a “soldermask”, an epoxy-based material such as a brominated novolac resin. Layer 411 has a height 411a. For many semiconductor devices, the preferred height 411a is between about 10 and 30 μm. A window in the layer exposes the metal of a patterned conductive line to become the second contact pad. The window has a lateral dimension 413. As depicted in FIG. 4, it is preferred that the window is approximately circular and the lateral dimension 413 represents its diameter. For alignment and assembly convenience, diameter 413 is preferably smaller than the diameter 403a of the deformed gold sphere. Consequently, it is preferred that the diameter 403a of the deformed gold sphere is greater than the lateral dimension 413 of the window.

In the next process step, tin is deposited in window 413 on top of the metal of the second pad. The preferred deposition method is plating, either by electroplating using a buss bar connection or by immersion plating without the buss bar. The deposited tin, indicated by shading 412 in FIG. 4, has a height 412a (which may reach as high as soldermask height 411a), resulting in volume Vₜᵢₙ. Designating Vₜᵢₙ the second volume, the calculations (see below) for the eutectic gold/tin composition require that the second volume be less than about two thirds of the first volume: Vₜᵢₙ<0.667 V_{stud}.

As indicated by line 420 in FIG. 4, the first and the second workpiece are aligned to bring the gold stud in contact with the tin layer. Thermal energy is then applied to the first and the second workpiece to reach a reflow temperature of a few degrees above the eutectic temperature 278° C. of gold and tin; for instance, a preferred temperature is 285° C. This temperature is maintained for a time sufficient to consume substantially all tin and a portion of the gold stud for forming the eutectic composition of 80 weight percent gold and 20 weight percent tin. The time at the reflow temperature is preferably between 20 and 60 s.

A calculation delivers the volume portion V_{gold} of the gold stud volume V_{stud} (with V_{gold}<V_{stud}) to be dissolved in order to consume all tin of volume Vₜᵢₙ.

In the eutectic composition, the weight W_{disgold} of the dissolved gold is 4 times the weight Wₜᵢₙ of the dissolved tin. With the specific weights for gold 19.32 and for tin 7.285, the eutectic composition requires

V_{disgold}·19.32=4·Vₜᵢₙ·7.285;

V_{disgold}=1.5 Vₜᵢₙ,

or Vₜᵢₙ=0.667 V_{disgold}

with Vₜᵢₙ<0.667 V_{stud}.

Considering the relatively small volume V_{stud} of gold balls in contemporary semiconductor devices, the needed volume Vₜᵢₙ of tin in the second contact pad is small indeed, especially when, for practical reasons, only the gold cone 404 of the scud should be consumed for forming the eutectic structure, while the more massive deformed sphere 403 should be preserved for purposes of absorbing thermo-mechanical stress.

Vₜᵢₙ can numerically be determined by selecting window diameter 413 and tin height 412a (see FIG. 4). V_{disgold} is found from cone diameter 404a and cone height 404b, when only cone 404 is dissolved.

As FIG. 2 illustrates, the eutectic structure 111 has preferably the outline of an approximate column with a diameter about equal to the later dimension 211 of the window.

In the next process step, the first and the second workpiece together with the metal interconnect of the eutectic structure and the leftover gold are cooled to ambient temperature. As stated above, the relatively high temperature of 278° C. for forming the eutectic composition prevents a re-melting of the eutectic structure in subsequent assembly steps, since these subsequent steps operate at reflow temperatures lower than the 278° C. eutectic temperature. Consequently, the gold content of the eutectic structure is stabilized (except for the negligible solid state diffusion).

As an example for subsequent assembly, many semiconductor devices require three more reflows: Attachment of the ball grid array solder bodies; attachment of a memory component package; and assembly on a mother board.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the embodiments are effective in semiconductor devices and any other device with contact pads, which have to undergo assembly on a substrate or printed circuit board followed by underfilling the gap between device and substrate. As another example, the semiconductor devices may include products based on silicon, silicon germanium, gallium arsenide and other semiconductor materials employed in manufacturing.

As yet another example, the concept of the invention is effective for many semiconductor device technology nodes and not restricted to a particular one. Especially, the invention provides a method for reliable chip-on-chip devices.

It is therefore intended that the appended claims encompass any such modifications or embodiments.

We claim:

1. An apparatus comprising:
a first workpiece having a first contact pad including a gold stud;
a second workpiece covered with an insulating layer and a window in the layer having a second contact pad; and
a 278° C. eutectic structure having about 80 weight percent gold and about 20 weight percent tin contacting the second pad and the gold stud.

2. The apparatus according to claim 1 wherein the first workpiece is a semiconductor chip.

3. The apparatus according to claim 2 wherein the first contact pad further includes a layer of aluminum between the gold stud and the semiconductor chip.

4. The apparatus according to claim 1 wherein the gold stud has the shape of a deformed sphere.

5. The apparatus according to claim 1 wherein the second workpiece is an insulating substrate.

6. The apparatus according to claim 1 wherein the eutectic structure has a Young's modulus of 59.2 GPa.

7. The apparatus according to claim 1 wherein the eutectic structure of 80 weight percent Au and 20 weight percent Sn has a lamellar micro-structure of the phases Au₅Sn and AuSn.

8. A method comprising the steps of:
providing a first workpiece including a first contact pad having a metal with a surface bondable to gold;
forming a free air gold ball from a gold wire, the ball having a size;
placing and squeezing the free air ball on the metal of the first contact pad to create a deformed sphere of a diameter;
breaking the wire from the sphere to leave a gold stud of a first volume on the first pad;
providing a second workpiece covered with an insulating layer of a height, a window in the layer exposing the metal of a second contact pad, the window having a lateral dimension;
depositing tin of a second volume on the metal of the second pad, the second volume less than about two thirds of the first volume;
aligning the first and the second workpiece to bring the gold stud in contact with the tin layer;
applying thermal energy to the first and the second workpiece to reach a reflow temperature of a few degrees above 278° C.;
maintaining the temperature for a time sufficient to consume substantially all tin and a portion of the gold stud for forming the eutectic mixture of 80 weight percent gold and 20 weight percent tin; and
cooling the first and the second workpiece together with the metal interconnect of the eutectic structure and the leftover gold to ambient temperature.

9. The method according to claim 8 wherein the leftover gold forms a stud shaped as a deformed sphere of a size sufficient to absorb thermomechanical stress.

10. The method according to claim 8 wherein the temperature a few degrees above 278° C. is about 285° C.

11. The method according to claim 8 wherein the first workpiece is a semiconductor chip and the metal bondable to gold is aluminum.

12. The method according to claim 8 wherein the gold wire has a diameter between about 15 to 30 μm.

13. The method according to claim 8 wherein the second workpiece is an insulating substrate having at least one metallization layer, and the metal of the second contact pad is copper.

14. The method according to claim 8 wherein the insulating layer is an epoxy-based material (such as brominated novolac resin, “soldermask”) and the layer height is between about 10 and 30 μm.

15. The method according to claim 8 wherein the diameter of the deformed gold sphere is greater than the lateral dimension of the window.

16. The method according to claim 8 wherein the window in the layer is approximately circular and has a diameter, which is smaller than the diameter of the deformed gold sphere.

17. The method according to claim 8 wherein the eutectic structure has the outline of an approximate column with a diameter about equal to the lateral dimension of the window.

18. The method according to claim 8 wherein, for the eutectic mixture of 80 weight percent gold and 20 weight percent tin, the dissolved portion of the first volume (gold) is 1.5 times the second volume (tin); the second volume (tin) is two thirds of the first volume (gold).

19. The method according to claim 8 wherein the time at the reflow temperature is between about 20 and 60 s.

20. The method according to claim 8 wherein the 278° C. melting temperature of the eutectic structure is higher than the reflow temperatures of subsequent assembly process steps, stabilizing the gold content of the structure.
